(19) United States
(12) Patent Application Publication
(10) Pub. No.: US 2019/0242425 A1
(43) Pub. Date: Aug. 8, 2019

(54) SCREW WITH ANTI-LOOSENING FEATURES

(71) Applicant: Dell Products L.P., Round Rock, TX (US)

(72) Inventors: Yu-Lin CHEN, Taipei (TW); Michael LO, Round Rock, TX (US)

(73) Assignee: Dell Products L.P., Round Rock, TX (US)

(21) Appl. No.: 15/887,726

(22) Filed: Feb. 2, 2018

(51) Int. Cl. F16B 39/282; H05K 7/14

(52) U.S. Cl. CPC F16B 39/282; H05K 7/1489

(57) ABSTRACT

A screw may include a head, a threaded cylindrical shaft mechanically coupled to the head such that an axis of the threaded cylindrical shaft extends from the head, and a plurality of substantially spaced serration features formed proximate to where the head is mechanically coupled to the threaded cylindrical shaft, each of the plurality of substantially spaced serration features mechanically coupled to the head and threaded cylindrical shaft. Each serration feature may include a displacer mechanically coupled to the head and the threaded cylindrical shaft and configured to, when the screw is driven into a receptacle for receiving the screw via a countersink, displace material of the countersink and an undercut mechanically coupled to the head and the threaded cylindrical shaft and configured to engage with the countersink in order to prevent the screw from disengaging from the countersink and the receptacle due to a mechanical force upon the screw.

### TECHNICAL FIELD

The present disclosure relates in general to information handling systems, and more particularly to a screw with anti-loosening features for use with an information handling system chassis.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Oftentimes, information handling systems and other information handling resources (e.g., storage devices, input/output devices, and other peripheral devices) are each manufactured in a modular form factor and may be configured to be disposed in a chassis configured to receive such modular components. Such a chassis and its component modular information handling systems and information handling resources typically include various rails, carriers, and other mechanical components allowing for a person to add and remove the modular information handling systems and information handling resources from the chassis. In some instances, fasteners such as screws may be used to mechanically fix an information handling resource to a rail, carrier, or other structure. However, such screws may be sensitive to vibration. For example, hard disk drives, cooling fans, and other electromechanical devices may cause vibration and/or other mechanical forces on such screws which may cause the screw to withdraw from its engagement with the information handling resource and/or the mechanical structure (e.g., rail, carrier, etc.) to which the information handling resource is mechanically coupled.

### SUMMARY

In accordance with the teachings of the present disclosure, the disadvantages and problems associated with vibrational effects on mechanical screws have been reduced or eliminated.

In accordance with embodiments of the present disclosure, a screw may include a head, a threaded cylindrical shaft mechanically coupled to the head such that an axis of the threaded cylindrical shaft extends from the head, and a plurality of substantially spaced serration features formed proximate to where the head is mechanically coupled to the threaded cylindrical shaft, each of the plurality of substantially spaced serration features mechanically coupled to the head and the threaded cylindrical shaft. Each serration feature may include a displacer mechanically coupled to the head and the threaded cylindrical shaft and configured to, when the screw is driven into a receptacle for receiving the screw via a countersink, displace material of the countersink and an undercut mechanically coupled to the head and the threaded cylindrical shaft and configured to engage with the countersink in order to prevent the screw from disengaging from the countersink and the receptacle due to a mechanical force upon the screw.

In accordance with these and other embodiments of the present disclosure, an information handling system may include a chassis, an information handling resource, a carrier mechanically coupled to the chassis and configured for receiving the information handling resource, and a screw for mechanically coupling the information handling resource to the carrier. The screw may include a head, a threaded cylindrical shaft mechanically coupled to the head such that an axis of the threaded cylindrical shaft extends from the head, and a plurality of substantially spaced serration features formed proximate to where the head is mechanically coupled to the threaded cylindrical shaft, each of the plurality of substantially spaced serration features mechanically coupled to the head and the threaded cylindrical shaft. Each serration feature may include a displacer mechanically coupled to the head and the threaded cylindrical shaft and configured to, when the screw is driven into a receptacle for receiving the screw via a countersink, displace material of the countersink and an undercut mechanically coupled to the head and the threaded cylindrical shaft and configured to engage with the countersink in order to prevent the screw from disengaging from the countersink and the receptacle due to a mechanical force upon the screw.

In accordance with these and other embodiments of the present disclosure, a method may include mechanically coupling a head of a screw to a threaded cylindrical shaft of the screw such that an axis of the threaded cylindrical shaft extends from the head and mechanically coupling a plurality of substantially spaced serration features proximate to where the head is mechanically coupled to the threaded cylindrical shaft, each of the plurality of substantially spaced serration features mechanically coupled to the head and the threaded cylindrical shaft, wherein each serration feature comprises a displacer mechanically coupled to the head and the threaded cylindrical shaft and configured to, when the screw is driven into a receptacle for receiving the screw via a countersink, displace material of the countersink and an undercut mechanically coupled to the head and the threaded cylindrical shaft and configured to engage with the countersink in order to prevent the screw from disengaging from the countersink and the receptacle due to a mechanical force upon the screw.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a perspective view of a chassis for receiving modular information handling resources, in accordance with embodiments of the present disclosure;

FIG. 2 illustrates an exploded perspective view of an example chassis drawer for receiving modular information handling resources, in accordance with embodiments of the present disclosure;

FIGS. 3A and 3B illustrate different perspective views of a screw with anti-loosening features, in accordance with embodiments of the present disclosure; and

FIG. 4 illustrates a side elevation view of a portion of the screw depicted in FIGS. 3A and 3B, in accordance with embodiments of the present disclosure.

### DETAILED DESCRIPTION

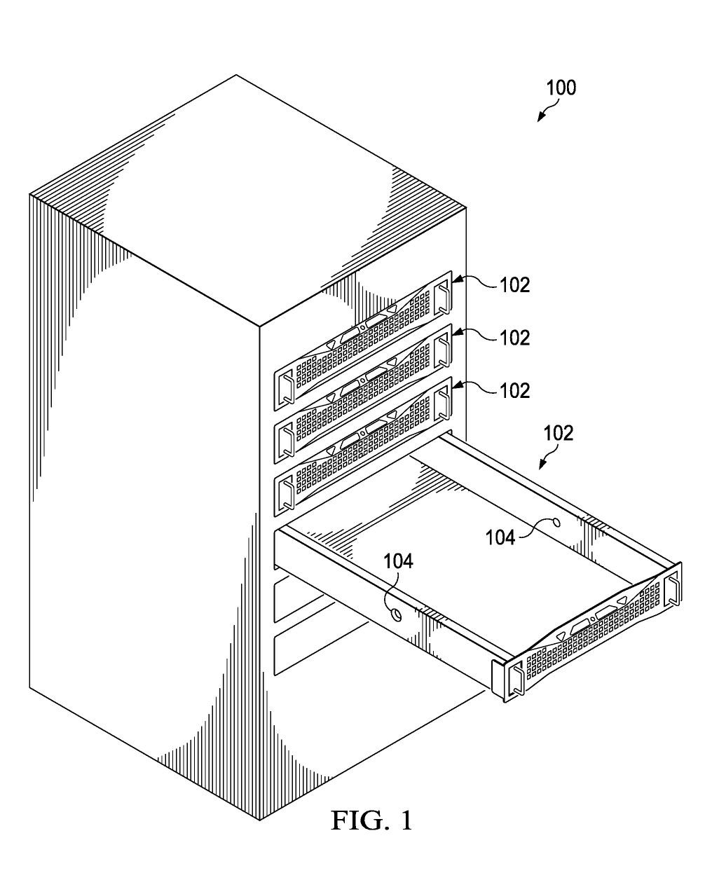

Preferred embodiments and their advantages are best understood by reference to FIGS. 1-4, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a personal digital assistant (PDA), a consumer electronic device, a network storage device, or any other suitable device and may vary in size, shape, performance, functionality, and price. The information handling system may include memory, one or more processing resources such as a central processing unit (“CPU”) or hardware or software control logic. Additional components of the information handling system may include one or more storage devices, one or more communications ports for communicating with external devices as well as various input/output (“I/O”) devices, such as a keyboard, a mouse, and a video display. The information handling system may also include one or more buses operable to transmit communication between the various hardware components.

For the purposes of this disclosure, information handling resources may broadly refer to any component system, device or apparatus of an information handling system, including without limitation processors, service processors, basic input/output systems, buses, memories, I/O devices and/or interfaces, storage resources, network interfaces, motherboards, and/or any other components and/or elements of an information handling system.

FIG. 1 illustrates a perspective view of a chassis 100 for receiving modular information handling resources, in accordance with embodiments of the present disclosure. Chassis 100 may be an enclosure that serves as a container for various information handling systems and information handling resources, and may be constructed from steel, aluminum, plastic, and/or any other suitable material. Although the term “chassis” is used, chassis 100 may also be referred to as a case, cabinet, tower, box, enclosure, and/or housing. In certain embodiments, chassis 100 may be configured to hold and/or provide power to a plurality of information handling systems and/or information handling resources. As depicted in FIG. 1, chassis 100 may include one or more drawers 102 for receiving information handling resources, as described in greater detail below. Also as depicted in FIG. 1, each drawer 102 may include countersinks 104 for receiving a screw or other fastener for mechanically fixing an information handling resource within and relative to drawer 102.

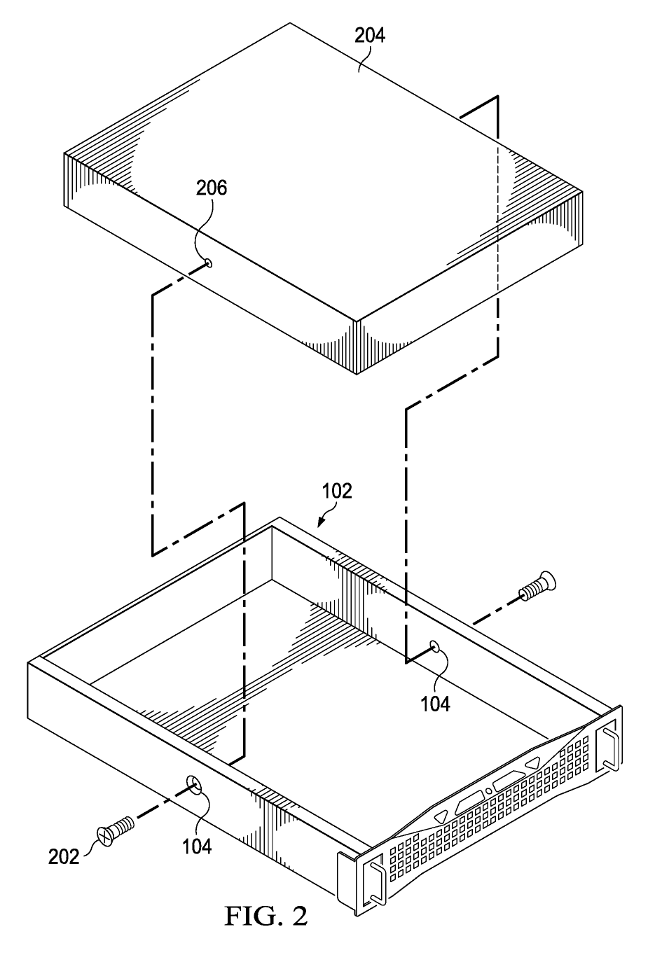

FIG. 2 illustrates an exploded perspective view of an example chassis drawer 102 for receiving modular information handling resources, in accordance with embodiments of the present disclosure. As shown in FIG. 2, chassis drawer 102 may receive an information handling resource 204, thus serving as a carrier for information handling resource 204. As also depicted in FIG. 2, chassis drawer 102 may receive a plurality of screws 202 via respective countersinks 104, and such screws 202 may further engage with a receptacle 206 of information handling resource 204, thus mechanically coupling information handling resource 204 to chassis drawer 102. In some embodiments, screws 202 and receptacles 206 may each be threaded to facilitate engagement of screws 202 within their respective receptacles 206.

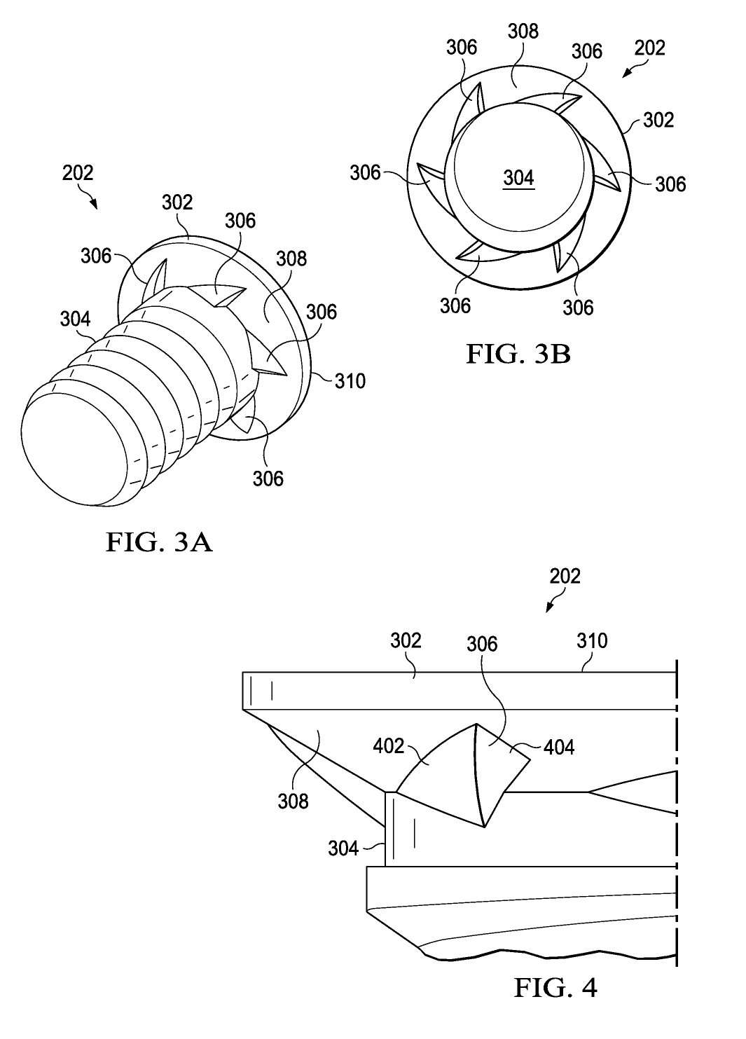

FIGS. 3A and 3B illustrate different perspective views of a screw 202 with anti-loosening features, in accordance with embodiments of the present disclosure. FIG. 3A illustrates an isometric perspective view while FIG. 3B illustrates a “bottom-up” plan view. As shown in FIGS. 3A and 3B, screw 202 may comprise a substantially disc-shaped screw head 302 coupled to a substantially cylindrical shaft 304. In some embodiments, a bottom surface 308 of screw head 302 (e.g., the surface of screw head 302 adjacent to cylindrical shaft 304) may be tapered from the edge of screw head 302 to cylindrical shaft 304. Also, although not shown in FIGS. 3A and 3B, a top surface 310 of screw head 302 may include features for facilitating engagement of a screwdriver with screw head 302 (e.g., features for engaging with a flat-head screwdriver, a Phillips screwdriver, a hexagonal screwdriver, or other screwdriver) to facilitate the mechanical driving of screw 202 by such screwdriver. Further, as shown in FIGS. 3A and 3B, the sides of cylindrical shaft 304 may be threaded to facilitate engagement of screw 202 with an appropriate receptacle. As also shown in FIGS. 3A and 3B, and as further described in greater detail below, screw 202 may include a plurality of spaced serration features 306 configured to engage with a countersink (e.g., a countersink 104) to prevent vibrational loosening of screw 202 when screw 202 is engaged with such countersink and a receptacle (e.g., receptacle 206). Although screw 202 is shown as including six serration features in FIGS. 3A and 3B, screw 202 may include any suitable number of serration features. As described above, serration features 306 may be spaced from each other in the sense that a distance between any two serration features 306 around a circumference of cylindrical shaft 304 is equal to or greater than the length of a single serration feature 306 around such circumference.

FIG. 4 illustrates a side elevation view of a portion of screw 202 depicted in FIGS. 3A and 3B, in accordance with embodiments of the present disclosure. As shown in FIG. 4, each serration feature 306 may include a displacer 402 and an undercut 404. Displacer 402 may be an approximately planar surface with a small degree of convexity, and such surface may be generally triangular in shape, with a first edge of such triangle coupled directly to bottom 308 of screw head 302, a second edge of such triangle coupled directly to cylindrical shaft 304, and a third edge extending from bottom 308 of screw head 302 to cylindrical shaft 304. Undercut 404 may be an approximately planar surface with a small degree of concavity, and such surface may be generally triangular in shape, with a first edge of such triangle coupled directly to bottom 308 of screw head 302, a second edge of such triangle coupled directly to cylindrical shaft 304, and a sharing third edge of the surface of displacer 402 which extends from bottom 308 of screw head 302 to cylindrical shaft 304.

In operation, when screw 202 is sufficiently driven into a respective receptacle 206 via a respective countersink 104 (e.g., when screw 202 is driven into receptacle 206 in a clockwise manner about the axis of cylindrical shaft 304), an inclined plane formed by displacer 402 functions to displace material of chassis drawer 102 around the circumference of countersink 104, allowing undercut 404 to engage such circumference of countersink 104 in a manner that prevents screw 202 from rotating in a counterclockwise manner relative to countersink 104 and receptacle 206, thus preventing screw 202 from loosening its engagement with countersink 104 and receptacle 206 (e.g., due to vibration or other mechanical forces).

Although the foregoing contemplates using screw 202 to mechanically fix an information handling resource to a carrier for such information handling resource, screw 202 as disclosed herein may be used in any other suitable application in which it is desired to mechanically couple one object to another using a screw or other fastener.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

What is claimed is:

1. A screw comprising:
a head;
a threaded cylindrical shaft mechanically coupled to the head such that an axis of the threaded cylindrical shaft extends from the head; and
a plurality of substantially spaced serration features formed proximate to where the head is mechanically coupled to the threaded cylindrical shaft, each of the plurality of substantially spaced serration features mechanically coupled to the head and the threaded cylindrical shaft and comprising:
a displacer mechanically coupled to the head and the threaded cylindrical shaft and configured to, when the screw is driven into a receptacle for receiving the screw via a countersink, displace material of the countersink; and
an undercut mechanically coupled to the head and the threaded cylindrical shaft and configured to engage with the countersink in order to prevent the screw from disengaging from the countersink and the receptacle due to a mechanical force upon the screw.

2. The screw of claim 1, wherein the mechanical force comprises a vibrational force.

3. The screw of claim 1, wherein the displacer comprises an approximately planar surface with convexity, wherein such surface is generally triangular in shape.

4. The screw of claim 3, wherein:
a first edge of the triangular shape of the displacer is coupled directly to a bottom of the head;
a second edge of the triangular shape of the displacer is coupled directly to the cylindrical shaft; and
a third edge of the triangular shape of the displacer extends from the bottom of the head to the cylindrical shaft.

5. The screw of claim 4, wherein:
a first edge of the triangular shape of the undercut is coupled directly to a bottom of the head;
a second edge of the triangular shape of the undercut is coupled directly to the cylindrical shaft; and
the undercut shares a third edge of the triangular shape of the undercut with the third edge of the triangular shape of the displacer.

6. An information handling system comprising:
a chassis;
an information handling resource;
a carrier mechanically coupled to the chassis and configured for receiving the information handling resource; and
a screw for mechanically coupling the information handling resource to the carrier, the screw comprising:
a head;
a threaded cylindrical shaft mechanically coupled to the head such that an axis of the threaded cylindrical shaft extends from the head; and
a plurality of substantially spaced serration features formed proximate to where the head is mechanically coupled to the threaded cylindrical shaft, each of the plurality of substantially spaced serration features mechanically coupled to the head and the threaded cylindrical shaft and comprising:
a displacer mechanically coupled to the head and the threaded cylindrical shaft and configured to, when the screw is driven into a receptacle of the information handling resource for receiving the screw via a countersink of the carrier, displace material of the countersink; and
an undercut mechanically coupled to the head and the threaded cylindrical shaft and configured to engage with the countersink in order to prevent the screw from disengaging from the countersink and the receptacle due to a mechanical force upon the screw.

7. The information handling system of claim 6, wherein the mechanical force comprises a vibrational force.

8. The information handling system of claim 6, wherein the displacer comprises an approximately planar surface with convexity, wherein such surface is generally triangular in shape.

9. The information handling system of claim 8, wherein:
a first edge of the triangular shape of the displacer is coupled directly to a bottom of the head;
a second edge of the triangular shape of the displacer is coupled directly to the cylindrical shaft; and
a third edge of the triangular shape of the displacer extends from the bottom of the head to the cylindrical shaft.

10. The information handling system of claim 9, wherein:
a first edge of the triangular shape of the undercut is coupled directly to a bottom of the head;
a second edge of the triangular shape of the undercut is coupled directly to the cylindrical shaft; and
the undercut shares a third edge of the triangular shape of the undercut with the third edge of the triangular shape of the displacer.

11. A method comprising:
mechanically coupling a head of a screw to a threaded cylindrical shaft of the screw such that an axis of the threaded cylindrical shaft extends from the head; and
mechanically coupling a plurality of substantially spaced serration features proximate to where the head is mechanically coupled to the threaded cylindrical shaft, each of the plurality of substantially spaced serration features mechanically coupled to the head and the threaded cylindrical shaft and comprising:
a displacer mechanically coupled to the head and the threaded cylindrical shaft and configured to, when the screw is driven into a receptacle for receiving the screw via a countersink, displace material of the countersink; and
an undercut mechanically coupled to the head and the threaded cylindrical shaft and configured to engage with the countersink in order to prevent the screw from disengaging from the countersink and the receptacle due to a mechanical force upon the screw.

12. The method of claim 11, wherein the mechanical force comprises a vibrational force.

13. The method of claim 11, wherein the displacer comprises an approximately planar surface with convexity, wherein such surface is generally triangular in shape.

14. The method of claim 13, wherein:
a first edge of the triangular shape of the displacer is coupled directly to a bottom of the head;
a second edge of the triangular shape of the displacer is coupled directly to the cylindrical shaft; and
a third edge of the triangular shape of the displacer extends from the bottom of the head to the cylindrical shaft.

15. The method of claim 14, wherein:
a first edge of the triangular shape of the undercut is coupled directly to a bottom of the head;
a second edge of the triangular shape of the undercut is coupled directly to the cylindrical shaft; and
the undercut shares a third edge of the triangular shape of the undercut with the third edge of the triangular shape of the displacer.
